(19) United States
(12) Patent Application Publication
(10) Pub. No.: US 2016/0254207 A1
(43) Pub. Date: Sep. 1, 2016

(54) Directional Heat Dissipation Assembly and Method

(71) Applicant: Jonathan Ryan Wilkerson, Morrisville, NC (US)

(72) Inventor: Jonathan Ryan Wilkerson, Morrisville, NC (US)

(21) Appl. No.: 15/154,755

(22) Filed: May 13, 2016

Related U.S. Application Data
(62) Division of application No. 14/280,543, filed on May 16, 2014.

(51) Int. Cl. H01L 23/367; H01L 25/065; H01L 23/373; H01L 29/78; H01L 23/528

(52) U.S. Cl. CPC H01L 23/367; H01L 29/78; H01L 23/528; H01L 23/3731; H01L 23/3735; H01L 25/0657; H01L 2225/06589

(57) ABSTRACT

A directional heat diffusion assembly and method helps self-cool a transistor by forcing directional heat flow from a heat source, such as from a transistor, group of transistors, integrated circuit, or other integrated heat source, to a heat reservoir at a bottom surface and/or a top surface of the transistor, while also preventing heat flow towards the sidewall of the transistor. The directional heat flow occurs through a directional heat guide member that is comprised of alternating, layered arrangement of thermal insulative layers, and thermal conductive layers having varying thermal conductivities. In this manner, dissipation of heat through a directional heat guide member is controlled by either alternating the thermal insulative and conductive layers, or by increasing the differences between the thermal conductivities for the thermal insulative layers and thermal conductive layers

### CROSS REFERENCE OF RELATED APPLICATIONS

This application claims the benefits of U.S. Nonprovisional application Ser. No. 14/280,543, filed May 16, 2014 and entitled FORCED DIRECTIONAL HEAT FLOW STRUCTURES AND METHODS, which Nonprovisional application is incorporated by reference herein in its entirety.

### FIELD OF THE INVENTION

The present invention relates generally to a directional heat dissipation assembly and method. More so, a directional heat dissipation assembly provides a directional heat guide member that draws heat away from the coupled transistor through a top surface and a bottom surface of the transistor, while also inhibiting the transfer of heat towards the sidewall of the transistor with a layered arrangement of insulative and conductive material

### BACKGROUND OF THE INVENTION

Typically, a transistor is a semiconductor device used to amplify or switch electronic signals and electrical power. It is composed of semiconductor material with at least three terminals for connection to an external circuit. Often, a voltage or current applied to one pair of the transistor's terminals changes the current through another pair of terminals. Because the controlled (output) power can be higher than the controlling (input) power, a transistor can amplify a signal.

Generally, transistors are utilized in electrical circuits of all types in order to process or alter information and signals in a beneficial manner. Electrical system performance and functionality of the transistor is often limited by heat dissipation in individual transistors or the net heat output of a group of transistors. Regardless of low power design methodologies and power management techniques, fundamentally there will always be some amount of electrical power dissipated, which is turned into heat.

It is known in the art that an integrated circuit level cooling solutions is used to remove heat from the transistor. Thus, there is a fundamental need for technologies to draw heat from a transistor, or other electrical heat source, without impacting its electrical performance or spreading the heat to other circuits in order to both increase performance and reduce cooling costs and complexity.

Further driving the need for cooling solutions for the transistor is the move to three-dimensional and stacked integrated circuits. Stacked integrated circuits lack a readily accessible thermal dissipation channel, especially in thinned die, causing significantly higher temperature rises in circuits that can inhibit performance severely. In addition, three-dimensional multi-gate transistors such as FinFETs continue to increase the power density, and thus heat generation, of integrated circuits.

Limited options currently exist to address overheating of transistors. Some technologies include thermal vias to increase the total thermal conductivity of each integrated circuit substrate, active thermoelectric cooling, and microfluidic cooling channels. There is a need for a device level solution that can control thermal gradients and temperature rise in stacked and three-dimensional integrated circuit structures.

Packaged integrated circuits, three-dimensional or two-dimensional, must be cooled at the motherboard level and at the housing facility level as well. At these levels, integrated circuits act as heaters in the facilities in which they are housed, which have to be cooled by HVAC or liquid cooling systems, often requiring significant energy to operate inside a facility. The heat is spread as quickly as possible in virtually all cooling solutions to the local air in order to guarantee electrical performance, resulting in large electronics operating costs. There is a need to reduce these cooling costs as well.

Other proposals have involved heat dissipating systems for integrated circuits and transistors. The problem with these systems is that they do not directionally guide the heat to a bottom and/or a top surface of a transistor.

Thus, an unaddressed need exists in the industry to address the aforementioned deficiencies and inadequacies. Even though the above cited methods for heat dissipation systems meets some of the needs of the market, a directional heat dissipation assembly provides a directional heat guide member that draws heat away from the coupled transistor through a top surface and a bottom surface of the transistor, while also inhibiting the transfer of heat towards the sidewall of the transistor with a layered arrangement of insulative and conductive material is still desired.

### SUMMARY OF THE INVENTION

The present invention is directed to a directional heat diffusion assembly and method for a transistor. The directional heat diffusion assembly and method is configured to directionally transfer heat from a heat source in a transistor, to a bottom surface and/or a top surface of the transistor, while also inhibiting the transfer of heat towards the sidewall of the transistor. In this manner, the heat is transferred away from sensitive electrical components, and towards heat dispersion components, such as a drain or a heat sink.

The directional heat diffusion system and method provides a directional heat guide member comprised of at least one thermal conductive layer and at least one thermal insulative layer that form layers on the transistor, and then sequentially on top of each other. In one embodiment, the thermal conductive layers and the thermal insulative layers have different thermal conductivity. The thermal conductive layers and the thermal insulative layers are also disposed in an alternating sequence pattern.

In one embodiment, a thermal insulative layer encases a thermal conductive layer, with each layer having a substantially different thermal conductivity. The thermal insulative layer, in essence traps the heat, while the thermal conductive layer directionally transfers the heat towards the bottom or top surface of the transistor, and away from the sidewalls of the transistor. Thus, the diffusion of heat from the transistor is controlled by alternating layers of the thermal conductive layers and the thermal insulative layers, and/or by increasing the disparity in thermal conductivities between the thermal conductive layers and the thermal insulative layers.

In one embodiment, the directional heat dissipation assembly comprises a transistor. The transistor is defined by a top surface, a bottom surface, and a sidewall. The transistor may include a heat source configured to generate heat. The directional heat dissipation assembly may further include a heat reservoir that is configured to enable storage and at least partial dissipation of the heat. The heat reservoir is disposed to join with the bottom surface of the transistor. The directional heat dissipation assembly may further include at least one conduction channel that is configured to carry an electrical current between the heat source and the heat reservoir.

The directional heat dissipation assembly may further include a coupling barrier that is disposed to operatively join with the heat source. The coupling barrier is further configured to join with at least a portion of the bottom surface of the transistor. The coupling barrier is further configured to enable electrical insulation at the bottom surface of the transistor. The coupling barrier is further configured to enable conduction of the heat from the heat source towards the heat reservoir.

In some embodiments, the directional heat dissipation assembly may further include a directional heat guide member that is configured to join with the coupling barrier. The directional heat guide member is further configured to directionally transfer the heat towards the bottom surface of the transistor and away from the top surface and the sidewall of the transistor. In one embodiment, the directional heat guide member comprises at least one of the following in a layered configuration:

The directional heat guide member may include a first thermal conductive layer formed to the bottom surface of the transistor. Specifically, the first thermal conductive layer encases the coupling barrier. In this manner, heat from the heat source transfers to the first thermal conductive layer through the coupling barrier. The first thermal conductive layer is defined by a first thermal conductivity, which is the property of the first thermal conductive layer to transfer heat.

The directional heat guide member may also include a first thermal insulative layer formed to the first thermal conductive layer. In one embodiment, the first thermal insulative layer fully encases the first thermal conductive layer. The first thermal insulative layer is defined by a second thermal conductivity, which is generally lower than the first thermal conductivity.

The directional heat guide member may also include a second thermal conductive layer formed to the first thermal insulative layer. In one embodiment, the second thermal conductive layer fully encases the first thermal insulative layer. The second thermal conductive layer is defined by a third thermal conductivity, which has a higher thermal conductivity than the second thermal conductivity. The third thermal conductivity is also about equal to the first thermal conductivity. Though in other embodiments, the third thermal conductivity may be more or less than the first thermal conductivity.

The directional heat guide member may also include a second thermal insulative layer formed to the second thermal conductive layer. In one embodiment, the second thermal insulative layer fully encases the second thermal conductive layer. The second thermal insulative layer is defined by a fourth thermal conductivity that is lower than the first thermal conductivity and the third thermal conductivity. Furthermore, the fourth thermal conductivity further is about equal to the second thermal conductivity. Though in other embodiments, the fourth thermal conductivity may be more or less than the second thermal conductivity. In this manner, the layers of the directional heat guide member are sequentially arranged in a layered configuration.

In another aspect, of the present invention, the directional heat guide member terminates layering at a terminal insulative layer.

In another aspect, the heat reservoir includes at least one member selected from the group consisting of: a drain, a heat sink, a thermoelectric cooler, a fluidic cooler, and a plurality of fins.

In another aspect, the assembly further includes a gate for implementing a Boolean function.

In yet another aspect, the assembly further includes a gate insulator.

In yet another aspect, the transistor rests on a substrate.

In yet another aspect, the transistor is a doped semiconductor.

In yet another aspect, the transistor is a bulk semiconductor.

In yet another aspect, the assembly further includes a plurality of electrical contacts.

In yet another aspect, the assembly further includes a plurality of optional terminations.

In yet another aspect, a material of the coupling barrier includes at least one member selected from the group consisting of: an oxide, a nitride, an oxynitride, and a ceramic.

In yet another aspect, the directional heat guide member is configured to transfer the heat to a second directional heat guide member.

In yet another aspect, the second thermal conductivity of the first thermal insulative layer and the fourth thermal conductivity of the second thermal insulative layer are less than 5 k.

In yet another aspect, the first thermal conductivity of the first thermal conductive layer and the third thermal conductivity of the second thermal conductive layer are at least 50 k.

In yet another aspect, the first thermal conductivity of the first thermal conductive layer and the third thermal conductivity of the second thermal conductive layer are 125 k to 400 k.

In yet another aspect, a material of the first thermal conductive layer and the second thermal conductive layer includes at least one member selected from the group consisting of: a metal, a semiconductor, and a ceramic.

In yet another aspect, the first thermal conductive layer fully encases the coupling barrier.

In yet another aspect, the first thermal insulative layer fully encases the first thermal conductive layer.

In yet another aspect, the second thermal conductive layer fully encases the first thermal insulative layer.

In yet another aspect, the second thermal insulative layer fully encases the second thermal conductive layer.

One objective of the present invention is to self-cool a transistor.

Another objective is to provide heat transfer towards a bottom surface and/or a top surface of a transistor.

Another objective is to inhibit heat transfer towards the sidewall of the transistor.

Another objective is to layer the thermal conductive layers and thermal insulative layers of material on the transistor.

Yet another objective is to diffuse heat from the transistor in a controlled manner by alternating layers of the thermal conductive layers and the thermal insulative layers.

Yet another objective is to provide the thermal conductive layers and thermal insulative layers with different thermal; conductivities.

Yet another objective is to diffuse heat from the transistor in a controlled manner by increasing the disparity in thermal conductivities between the thermal conductive layers and the thermal insulative layers.

Yet another objective is to provide a cost effective cooling assembly for transistors, semiconductors, three dimensional multi-gate transistors, and stacked integrated circuits.

Other systems, devices, methods, features, and advantages will be or become apparent to one with skill in the art upon examination of the following drawings and detailed description. It is intended that all such additional systems, methods, features, and advantages be included within this description, be within the scope of the present disclosure, and be protected by the accompanying claims and drawings.

### BRIEF DESCRIPTION OF THE DRAWINGS

The invention will now be described, by way of example, with reference to the accompanying drawings, in which:

FIG. 1 illustrates a diagram of an exemplary directional heat dissipation assembly generating heat and dissipating the heat through an exemplary directional heat guide member to an exemplary heat reservoir, in accordance with an embodiment of the present invention;

FIG. 2 illustrates a cross section view of a directional heat guide member going through a first thermal conductive layer, in accordance with an embodiment of the present invention;

FIG. 3 illustrates a cross section view of a directional heat guide member formed entirely in isolation trenches, in accordance with an embodiment of the present invention;

FIG. 4 illustrates a top view of a transistor, a directional heat guide member, and a structure for non-routed heat guides, in accordance with an embodiment of the present invention;

FIG. 5 illustrates a cross section view of a directional heat guide member with a heat conduction port contacting a bottom surface of the transistor only and porting heat to the bottom of a substrate, in accordance with an embodiment of the present invention;

FIG. 6 illustrates a top view of a transistor showing thermal insulative layers surrounding the transistor, in accordance with an embodiment of the present invention; and

FIG. 7 illustrates a cross section view of a group of transistors coupled to a thermal guide for directional heat flow control, in accordance with an embodiment of the present invention.

Like reference numerals refer to like parts throughout the various views of the drawings.

### DETAILED DESCRIPTION OF THE INVENTION

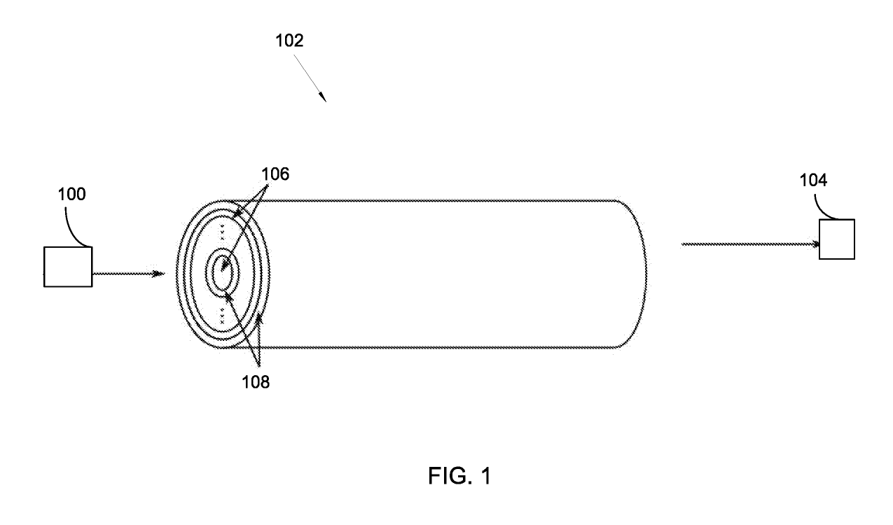

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “first,” “second,” “left,” “rear,” “right,” “front,” “vertical,” “horizontal,” and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

At the outset, it should be clearly understood that like reference numerals are intended to identify the same structural elements, portions, or surfaces consistently throughout the several drawing figures, as may be further described or explained by the entire written specification of which this detailed description is an integral part. The drawings are intended to be read together with the specification and are to be construed as a portion of the entire “written description” of this invention as required by 35 U.S.C. §112.

In one embodiment of the present invention presented in FIGS. 1-7, a directional heat diffusion assembly 100 and method helps self-cool a transistor 130 by forcing directional heat flow from a heat source 120, such as from a transistor 130, group of transistors 200a, 200b, integrated circuit, or other integrated heat source, to a heat reservoir 104 at a bottom surface 124 and/or a top surface 122 of the transistor 130, while also preventing heat flow towards the sidewall 126 of the transistor 130. In one embodiment, the directional heat flow occurs through a directional heat guide member 102 that is comprised of alternating, layered arrangement of thermal insulative layers 108, 112 and thermal conductive layers 106, 110 having varying thermal conductivities.

For example, in one embodiment, the thermal insulative layers 108, 112 and the thermal conductive layers 106, 110 alternate, and are defined by a significant difference in their thermal conductivity. In this manner, the dissipation of heat through a directional heat guide member 102 is controlled by either alternating the thermal insulative and conductive layers, or by increasing the differences between the thermal conductivities for the thermal insulative layers 108, 112 and thermal conductive layers 106, 110.

As FIG. 1 references, the directional heat diffusion assembly 100 is configured to directionally transfer heat from a heat source 120 in a transistor 130, to a bottom surface 124 of the transistor 130, while also inhibiting the transfer of heat towards the sidewall 126 of the transistor 130. Though in some embodiments, the heat is transferred to the bottom surface 124 and the top surface 122 of the transistor 130. In this manner, the heat may be transferred away from sensitive electrical components, and towards heat dispersion components, such as a drain or a heat sink.

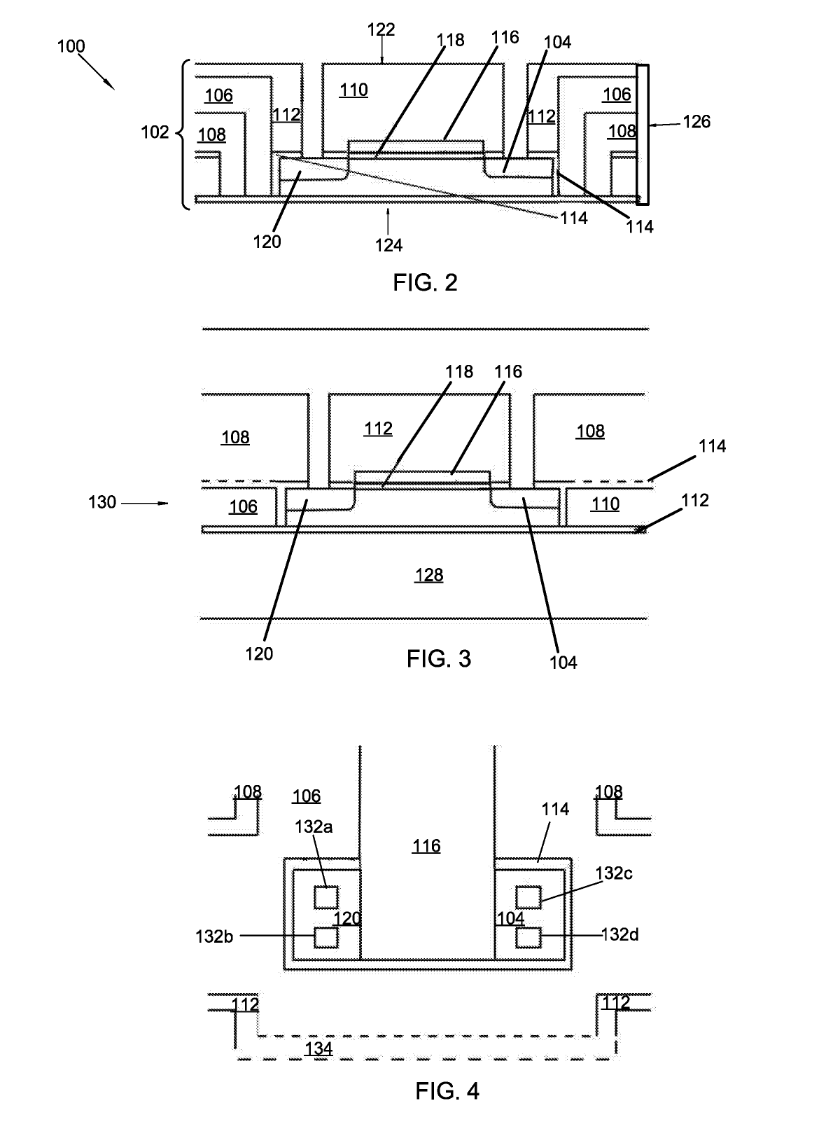

Turning now to FIG. 2, the directional heat diffusion assembly 100 provides at least one thermal conductive layer 106, 110 and at least one thermal insulative layer 108, 112 that form layers on the transistor 130, and then sequentially on top of each other. In one embodiment, the thermal conductive layers 106, 110 and the thermal insulative layers 108, 112 have different thermal conductivity. The thermal conductive layers 106, 110 and the thermal insulative layers 108, 112 are also disposed in an alternating sequence pattern.

In one embodiment, a first thermal insulative layer 108 encases a thermal conductive layer 106, with each layer having a substantially different thermal conductivity. The thermal insulative layer 108, in essence traps the heat, while the thermal conductive layer 106 directionally transfers the heat towards the bottom surface 124 or top surface 122 of the transistor 130, and away from the sidewall 126 of the transistor 130. Thus, the diffusion of heat from the transistor 130 is controlled by alternating layers of the thermal conductive layers 106, 110 and the thermal insulative layers 108, 112, and/or by increasing the disparity in thermal conductivities between the thermal conductive layers 106, 110 and the thermal insulative layers 108, 112.

In one embodiment, the directional heat dissipation assembly 100 comprises a transistor 130. In some embodiments, the transistor 130 may include, without limitation, semiconductors, three dimensional multi-gate transistors, stacked integrated circuits, and a group of transistors 200a, 200b. The assembly 100 may further include a gate 116 for implementing a Boolean function, and a gate insulator 118 for insulating the gate 116. In one embodiment, the transistor 130 rests on a substrate. In another embodiment, the transistor 130 is a doped semiconductor. In yet another embodiment, the transistor 130 is a bulk semiconductor 128.

Looking back at FIG. 2, the transistor 130 is defined by a top surface 122, a bottom surface 124, and a sidewall 126. The transistor 130 may provide a heat source 120 that generates heat during operation of the transistor 130. The directional heat dissipation assembly 100 may further include a heat reservoir 104 that is configured to enable storage and at least partial dissipation of the heat. The heat reservoir 104 is disposed to join with the bottom surface 124 of the transistor 130. In some embodiments, the heat reservoir 104 may include, without limitation, a drain, a heat sink, a thermoelectric cooler, a fluidic cooler, a plurality of fins, and a second transistor 130. The directional heat dissipation assembly 100 may further include at least one conduction channel (not shown) that is configured to carry an electrical current between the heat source 120 and the heat reservoir 104.

As shown in FIG. 3, the directional heat dissipation assembly 100 may further include a coupling barrier 114 that is disposed to operatively join with the heat source 120. The coupling barrier 114 is further configured to join with at least a portion of the bottom surface 124 of the transistor 130. The coupling barrier 114 is further configured to enable electrical insulation at the bottom surface 124 of the transistor 130. The coupling barrier 114 is further configured to enable conduction of the heat from the heat source 120 towards the heat reservoir 104. Suitable materials for the coupling barrier 114 may include, without limitation, an oxide, a nitride, an oxynitride, and a ceramic.

Looking at FIG. 4, the directional heat dissipation assembly 100 may further include a directional heat guide member 102 that is configured to join with the coupling barrier 114. The directional heat guide member 102 is further configured to directionally transfer the heat towards the bottom surface 124 of the transistor 130 and away from the sidewall 126 of the transistor 130. In one embodiment, the directional heat guide member 102 comprises at least one of the following in a layered configuration:

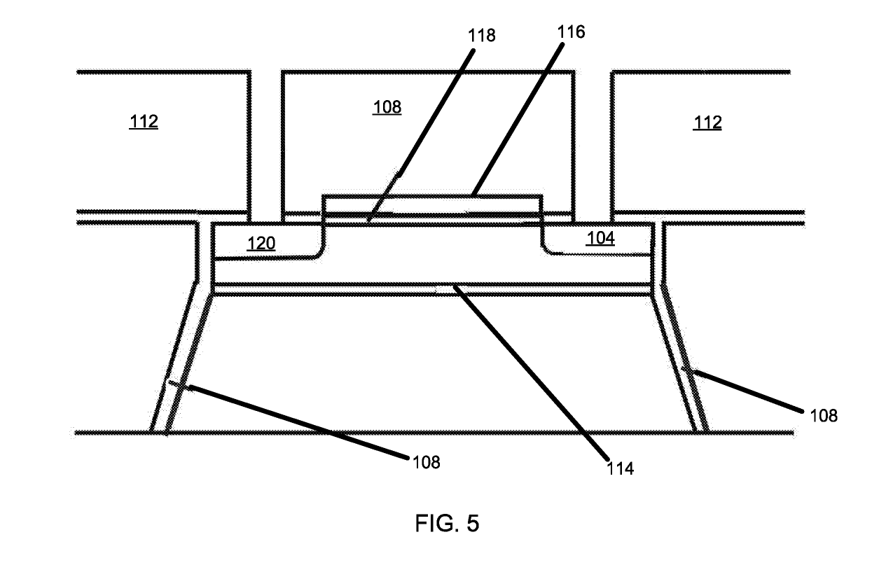

As FIG. 5 illustrates, the directional heat guide member 102 may include a first thermal conductive layer 106 formed to the bottom surface 124 of the transistor 130. Specifically, the first thermal conductive layer 106 encases the coupling barrier 114. In this manner, heat from the heat source 120 transfers to the first thermal conductive layer 106 through the coupling barrier 114. The first thermal conductive layer 106 is defined by a first thermal conductivity, which is the property of the first thermal conductive layer 106 to transfer heat. Suitable materials for the first thermal conductive layer 106 may include, without limitation, a metal, a semiconductor, or a ceramic.

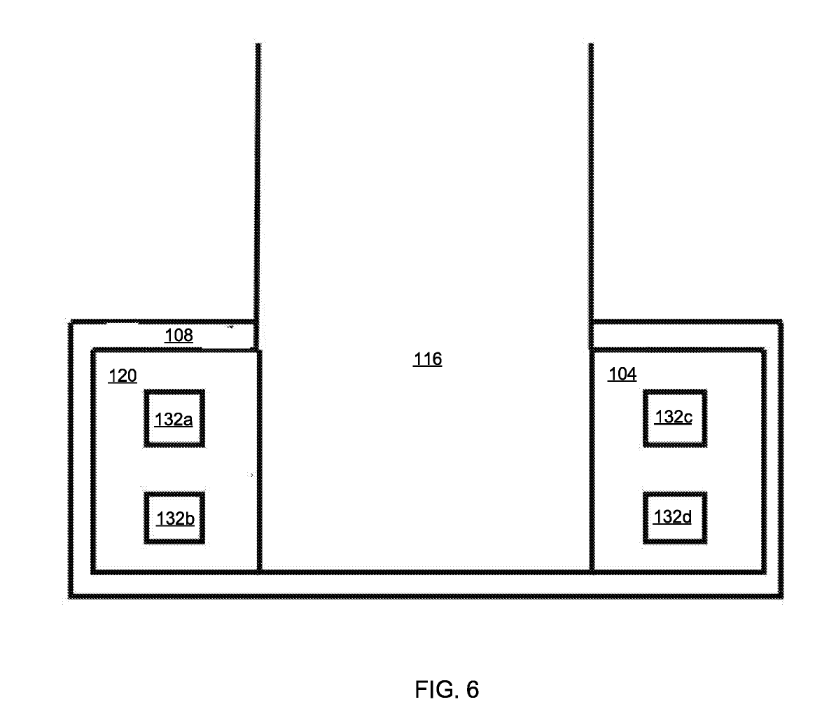

FIG. 6 illustrates a top view of a transistor 130 showing thermal insulative layers 108, 112 surrounding the transistor 130. The directional heat guide member 102 may also include a first thermal insulative layer 108 formed to the first thermal conductive layer 106. In one embodiment, the first thermal insulative layer 108 fully encases the first thermal conductive layer 106. The first thermal insulative layer 108 is defined by a second thermal conductivity, which is generally lower than the first thermal conductivity.

The directional heat guide member 102 may also include a second thermal conductive layer 110 formed to the first thermal insulative layer 108. In one embodiment, the second thermal conductive layer 110 fully encases the first thermal insulative layer 108. The second thermal conductive layer 110 is defined by a third thermal conductivity, which has a higher thermal conductivity than the second thermal conductivity. The third thermal conductivity is also about equal to the first thermal conductivity. Though in other embodiments, the third thermal conductivity may be more or less than the first thermal conductivity.

The directional heat guide member 102 may also include a second thermal insulative layer 112 formed to the second thermal conductive layer 110. In one embodiment, the second thermal insulative layer 112 fully encases the second thermal conductive layer 110. The second thermal insulative layer 112 is defined by a fourth thermal conductivity that is lower than the first thermal conductivity and the third thermal conductivity. Furthermore, the fourth thermal conductivity further is about equal to the second thermal conductivity. Though in other embodiments, the fourth thermal conductivity may be more or less than the second thermal conductivity. In this manner, the layers of the directional heat guide member 102 are sequentially arranged in a layered configuration.

In another embodiment, of the present invention, the directional heat guide member 102 terminates layering at a terminal insulative layer. In yet another aspect, the assembly 100 further includes a plurality of electrical contacts 132a-d. In yet another aspect, the assembly 100 further includes an optimal terminations 134. In yet another aspect, the directional heat guide member 102 is configured to transfer the heat to a second directional heat guide member 102.

As referenced in FIG. 2, the first thermal conductive layer 106 forms to the bottom surface 124, and specifically to the coupling barrier 114 on the bottom surface 124 of the transistor 130. The first thermal conductive layer 106 is a high thermal conductivity material, is encased in the first thermal insulative layer 108, having a lower thermal conductivity material composition.

In continuing the layering characteristic of the present invention, the first thermal insulative layer 108 is encased in the second thermal conductive layer 110, which has higher thermal conductivity than the first thermal insulative layer 108 but is not necessarily equal to the thermal conductivity of the first thermal conductive layer 106. The second thermal conductive layer 110 is encased in the second thermal insulative layer 112, which has lower thermal conductivity than the second thermal conductive layer 110 but is not necessarily equal to the first thermal insulative layer 108.

In this manner, the layered arrangement of the directional heat guide member 102 can be continued for any desired number of layers according to heat leakage suppression requirements, but can be as few as one layer of thermal conductive layer and thermal insulative layer. The layered arrangement is always terminated in a thermal insulative layer

At least thermal conductor one, but up to thermal conductor N, must be connected to a heat source 120 either directly or through a coupling barrier 114 material that can also provide electrical isolation. Said coupling barrier 114 material can be an oxide, nitride, oxynitride, ceramic, or other material.

The thermal insulator of the outermost thermal conductor that is in contact with the heat source 120 must be at least partially surrounding the heat source 120 to cause efficient coupling into the directional heat guide. The directional heat guide is terminated on the other end by either another directional heat guide or by a heat removal method such as a heat sink, thermoelectric cooler, fluidic cooling, or other applicable method.

A directionally heat guided transistor is a transistor that has thermal isolation at least partially surrounding it with at least one thermal guide connected to its source, drain, or conduction channel through a coupling barrier 114. The coupled thermal guide directs the heat generated by the transistor 130 to the surface, top or bottom, of the transistor 130 for removal via another directional heat guide if routing through another chip or to a heat removal mechanism.

Those skilled in the art will recognize that a directional heat guide is a structure that confines heat and guides it in a single, preferred direction away from a heat source 120. The directional heat guide structure is formed by alternating layers of a material with thermal conductivity k₁, k₃, k₅, k₍ₙ₋₁₎ with layers of a material with thermal conductivity k₂, k₄, k₆, kₙ where material i always has lower thermal conductivity than material₍ᵢ₋₁₎ and material₍ᵢ₋₁₎ has higher thermal conductivity than material₍ᵢ₋₂₎.

In some embodiments, the second thermal conductivity of the first thermal insulative layer 108 and the fourth thermal conductivity of the second thermal insulative layer 112 are less than 5 k. In other embodiments, the first thermal conductivity of the first thermal conductive layer 106 and the third thermal conductivity of the second thermal conductive layer 110 are at least 50 k. In other embodiments, the first thermal conductivity of the first thermal conductive layer 106 and the third thermal conductivity of the second thermal conductive layer 110 are between 125 k to 400 k.

As illustrated in FIG. 2, the bottom surface 124 of the transistor 130 at the heat source 120, drain, and bulk semiconductor including the conduction channel are at least partially bordered by a thermal insulator, preferably an oxide, but any material with low thermal conductivity, preferably k<=5. The sides or the source, drain, and bulk including the conduction channel are contacted by a coupling barrier 114 which is an electrical insulator, preferably having thermal conductivity of 10 or greater, which could be a nitride, oxynitride, or other suitable material.

As discussed above, the coupling barrier 114 is contacted directly by a high thermal conductivity material, the thermal conductor, with k at least >50, but preferably 125-400 or more, which could be a metal, semiconductor, or ceramic. The high thermal conductor material is bordered on the bottom by the thermal insulative layers 108, 112 contacting the bottom surface 124 of the source, drain, and bulk including the conduction channel. The thermal conductivity layer 106, 110 is also bordered on the sides and top by a thermal insulative layer 108, 112 (k<=5).

The directional heat guide member 102 can be routed in any direction, or in many directions, away from the transistor 130. Any area of the thermal conductive layer that is not to be routed is terminated in a thermal insulator (k<=5), shown in FIG. 4. The heat travels through said directional heat guide to either a heat reservoir 104, which is also completely encased in a thermal insulator, or to the top of the chip through a set of vias that are not connected to any other laterally routed metal other than the heat guide itself and are completely surrounded by a thermal insulator (k<=5), or to the bottom of the chip through a through silicon via that is completely encased in thermal insulator (k<=5).

The heat guide can be formed at the same level as the heat source 120, drain, and conduction channel, as shown in FIG. 2, or can be transferred to higher layers as in FIG. 3. Additionally, for multi-gate three dimensional transistors with very small conduction channels such as FinFETs, directional heat guides are formed in the same structure but only contact the drain and source of the transistor 130.

For multiple die systems where the die are mounted on top of each other, the directional heat guides of one chip may be directly coupled to the second chip to maintain directional thermal transport and isolation between chips until a heat removal point is reached. In this case, the thermal conductor of each directional thermal guide is recessed beneath a thermal insulator and then connected through solder or a thermal coupling compound to each other. The thermal coupling compound or solder is applied in such a way as to not contact any other surface that is not thermally insulated.

Yet another embodiment of a directionally heat dissipation assembly 100 is shown in the cross section of FIG. 3 and the top view in FIG. 4. Here the bottom surface 124 of the transistor 130, the heat source 120, a drain, and a bulk including the conduction channel are completely bordered by a coupling barrier 114 which is an electrical insulator, preferably having thermal conductivity (k) of 10 or greater, which could be a nitride, oxynitride, or other suitable material. The sides or the source, drain, and bulk including the conduction channel are contacted by a thermal insulator, preferably an oxide, but any material with low thermal conductivity, preferably k<=5, which further extends through the substrate to the bottom of the chip.

The coupling barrier 114 and thermal insulator is contacted directly by a high thermal conductivity material, the thermal conductor, with k at least >50, but preferably 125-400 or more, which could be a metal, semiconductor, or ceramic. The heat travels through said directional heat guide to the bottom of the chip where it contacts a heat removal mechanism or a second directional heat guide.

In a second embodiment, a structure of a transistor 130 with heat guiding structures for source, drain, and bulk regions including the conduction channel includes a directional heat guide member 102 composed of at least one layer or more of thermal conductivity layers encased in thermal insulative layers. The directional heat guide member 102 is connected to a heat source 120, drain, or bulk semiconductor 128 region, with connection to a heat source 120 or heat reservoir 104, i.e., drain region through a coupling barrier 114 that provides electrical isolation, and then connecting to the thermal conductor of the directional heat guide member 102.

In one exemplary use, the encasing thermal insulative layer 108 should be at least partially insulating the drain or source region. The directional heat guide member 102 should extend to a desired heat removal location, preferably, but not limited to, either a heat reservoir 104 or vertical directional heat guide, and finally coupled to a second directional heat guide in another die or a heat removal point.

In a third embodiment of the present disclosure, a structure of a transistor 130 with a vertical heat guiding structure for source, drain, and channel regions includes: a transistor 130 surrounded along its perimeter by thermal insulator at least equal to the depth of the source and drain regions; an electrical insulator that is thermally conductive to a degree contacting the bottom of the transistor 130 or substrate directly under the transistor 130 within the thermally insulated region; and a directional heat guide which connects vertically through to the electrically insulating partially thermally conductive region.

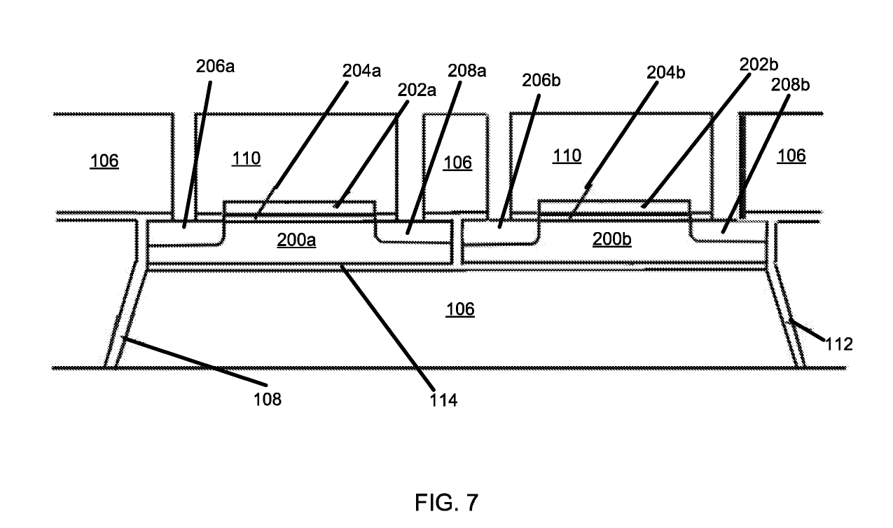

FIG. 7 illustrates a cross section view of a group of transistors coupled to a thermal guide for directional heat flow control. Thus, the directional heat guide member can encase a number of transistors where the outermost transistor define the thermal insulator of the heat guide. In a fourth embodiment of the present disclosure shown in FIG. 7, a structure of a group of transistors 200a, 200b with vertical heat guiding members regions includes: a group of transistors 200a, 200b surrounded along their perimeter by thermal insulative layer at least equal to the depth of the source and drain regions; an electrical insulator that is thermally conductive to a degree contacting the bottom of the transistors or substrate directly under the transistors within the thermally insulated region; and a directional thermal guide member which connects vertically through to the electrically insulating partially thermally conductive region. Further including a group of gates 202a, 202b; a group of gate insulators 204a, 204b; a group of heat sources 206a, 206b, and a group of heat reservoirs 208a, 208b.

In conclusion, the directional heat diffusion assembly 100 helps self-cool a transistor 130 by forcing directional heat flow from a heat source 120, such as from a transistor 130, group of transistors 200a, 200b, integrated circuit, or other integrated heat source, to a heat reservoir 104 at a bottom surface 124 and/or a top surface 122 of the transistor 130, while also preventing heat flow towards the sidewall 126 of the transistor 130. In one embodiment, the directional heat flow occurs through a directional heat guide member 102 that is comprised of alternating, layered arrangement of thermal insulative layers 108, 112 and thermal conductive layers 106, 110 having varying thermal conductivities. In this manner, the dissipation of heat through a directional heat guide member 102 is controlled by either alternating the thermal insulative and conductive layers, or by increasing the differences between the thermal conductivities for the thermal insulative layers 108, 112 and thermal conductive layers.

Since many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalence.

What I claim is:

1. A directional heat dissipation assembly, the assembly comprising:
a transistor, the transistor defined by a top surface, a bottom surface, and a sidewall, the transistor comprising a heat source configured to generate heat;
a heat reservoir, the heat reservoir configured to enable storage and at least partial dissipation of the heat, the heat reservoir disposed to join with the bottom surface of the transistor;
at least one conduction channel, the at least one conduction channel configured to carry an electrical current between the heat source and the heat reservoir;
a coupling barrier, the coupling barrier disposed to operatively join with the heat source, the coupling barrier configured to join with at least a portion of the bottom surface of the transistor, the coupling barrier further configured to enable electrical insulation at the bottom surface of the transistor, the coupling barrier further configured to enable conduction of the heat from the heat source towards the heat reservoir;
a directional heat guide member, the directional heat guide member configured to join with the coupling barrier, the directional heat guide member further configured to directionally transfer the heat towards the bottom surface of the transistor and away from the top surface and the sidewall of the transistor, the directional heat guide member comprising at least one of the following:
a first thermal conductive layer formed to the coupling barrier or the bottom surface of the transistor, the first thermal conductive layer defined by a first thermal conductivity;
a first thermal insulative layer formed to the first thermal conductive layer, the first thermal insulative layer defined by a second thermal conductivity configured to be lower than the first thermal conductivity;
a second thermal conductive layer formed to the first thermal insulative layer, the second thermal conductive layer defined by a third thermal conductivity configured to be higher than the second thermal conductivity, the third thermal conductivity further configured to be about equal to the first thermal conductivity; and
a second thermal insulative layer formed to the second thermal conductive layer, the second thermal insulative layer defined by a fourth thermal conductivity, the fourth thermal conductivity configured to be lower than the first thermal conductivity and the third thermal conductivity, the fourth thermal conductivity further configured to be about equal to the second thermal conductivity,
whereby the layers are sequentially arranged in a layered configuration.

2. The assembly of claim 1, further comprising additional layers of thermal conductive layers and thermal insulative layers fully wrapping all prior layers of thermal conductive layers and thermal insulative layers for the entire length of the directional heat guide member.

3. The assembly of claim 1, wherein the directional heat guide member terminates layering at a terminal insulative layer.

4. The assembly of claim 1, wherein the heat reservoir includes at least one member selected from the group consisting of: a drain, a heat sink, a thermoelectric cooler, a fluidic cooler, and a plurality of fins.

5. The assembly of claim 1, further including a gate for implementing a Boolean function.

6. The assembly of claim 1, further including a gate insulator.

7. The assembly of claim 1, wherein the transistor rests on a substrate.

8. The assembly of claim 1, wherein the transistor is a doped semiconductor.

9. The assembly of claim 1, wherein the transistor is a bulk semiconductor.

10. The assembly of claim 1, further including a plurality of electrical contacts.

11. The assembly of claim 1, further including a plurality of optional terminations.

12. The assembly of claim 1, wherein a material of the coupling barrier includes at least one member selected from the group consisting of: an oxide, a nitride, an oxynitride, and a ceramic.

13. The assembly of claim 1, wherein the second thermal conductivity of the first thermal insulative layer and the fourth thermal conductivity of the second thermal insulative layer are less than 5 k.

14. The assembly of claim 1, wherein the first thermal conductivity of the first thermal conductive layer and the third thermal conductivity of the second thermal conductive layer are at least 50 k.

15. The assembly of claim 1, wherein the first thermal conductivity of the first thermal conductive layer and the third thermal conductivity of the second thermal conductive layer are between 125 k to 400 k.

16. The assembly of claim 1, wherein a material of the first thermal conductive layer and the second thermal conductive layer includes at least one member selected from the group consisting of: a metal, a semiconductor, and a ceramic.

17. The assembly of claim 1, wherein the directional heat guide member is configured to transfer the heat to a second directional heat guide member.

18. The assembly of claim 1, further comprising a plurality of ends where at least the first thermal insulative layer at least partially encases the heat reservoir or a thermal conductivity layer from the second directional heat guide member, and further the first thermal conductive layer is in direct mechanical contact with the heat reservoir or the thermal conductivity layer of the second directional heat guide member.

19. The assembly of claim 18, further comprising a vertical via stack configured to be routed from the heat reservoir or the directional heat guide member, directly to a second heat reservoir on a die surface.

20. A directional heat dissipation assembly, the assembly comprising:
a transistor, the transistor defined by a top surface, a bottom surface, and a sidewall, the transistor comprising a heat source configured to generate heat;
a heat reservoir, the heat reservoir configured to enable storage and at least partial dissipation of the heat, the heat reservoir disposed to join with the bottom surface of the transistor;
at least one conduction channel, the at least one conduction channel configured to carry an electrical current between the heat source and the heat reservoir;
a coupling barrier, the coupling barrier disposed to operatively join with the heat source, the coupling barrier configured to join with at least a portion of the bottom surface of the transistor, the coupling barrier further configured to join with at least a portion of the top surface of the transistor, the coupling barrier further configured to enable electrical insulation at the bottom surface and the top surface of the transistor, the coupling barrier further configured to enable conduction of the heat from the heat source towards the heat reservoir from the bottom surface and the top surface of the transistor;
a directional heat guide member, the directional heat guide member configured to join with the coupling barrier, the directional heat guide member further configured to directionally transfer the heat towards the bottom surface and the top surface of the transistor, the directional heat guide member further configured to directionally transfer the heat away from the sidewall of the transistor, the directional heat guide member comprising at least one of the following:
a first thermal conductive layer formed to the coupling barrier, the bottom surface, or the top surface of the transistor, the first thermal conductive layer defined by a first thermal conductivity;
a first thermal insulative layer formed to the first thermal conductive layer, the first thermal insulative layer defined by a second thermal conductivity configured to be lower than the first thermal conductivity;
a second thermal conductive layer formed to the first thermal insulative layer, the second thermal conductive layer defined by a third thermal conductivity configured to be higher than the second thermal conductivity, the third thermal conductivity further configured to be about equal to the first thermal conductivity; and
a second thermal insulative layer formed to the second thermal conductive layer, the second thermal insulative layer defined by a fourth thermal conductivity, the fourth thermal conductivity configured to be lower than the first thermal conductivity and the third thermal conductivity, the fourth thermal conductivity further configured to be about equal to the second thermal conductivity,
whereby the layers are sequentially arranged in a layered configuration.
